(19) United States
(12) Patent Application Publication
(10) Pub. No.: US 2002/0170497 A1
(43) Pub. Date: Nov. 21, 2002

(54) Device for forming nanostructures on the surface of a semiconductor wafer by means of ion beams

(76) Inventors: Valery Konstantinovich Smirnov, Yaroslavl (RU); Dmitry Stanislavovich Kibalov, Yaroslavl (RU)

Correspondence Address: FAY KAPLUN & MARCIN, LLP, 15O BROADWAY, SUITE 702, NEW YORK, NY, 10038, US

(21) Appl. No.: 10/069,656

(22) PCT Filed: Jul. 2, 2001
(86) PCT No.: PCT/RU01/00261

(30) Foreign Application Priority Data
Jul. 4, 2000 (RU) 2000117335

(51) Int. Cl. C23C 16/00

(52) U.S. Cl. 118/723 E

(57) ABSTRACT

The invention makes it possible to develop the devices for producing nanostructures which are used for manufacturing the semiconductor items having high resolution optical instruments. The inventive device comprises a vacuum chamber provided with a pumping and annealing system, a unit for introducing the semiconductor wafers into the chamber, a controllable energy ion source, a mass-separator, an electron detector, a holder for the semiconductor wafer, a device for measuring the ion current, a quadrupole mass-analyzer and a computer provided with a monitor and interface. Axes of column of the ion beam transportation, an optical microscope and electron projector are arranged on the same plane as a normal line to the semiconductor wafer in a working position thereof and intercross at the same point on the front face of the wafer. An optical microscope and electron projector are arranged on the front face of the wafer and have a minimal angle therebetween.

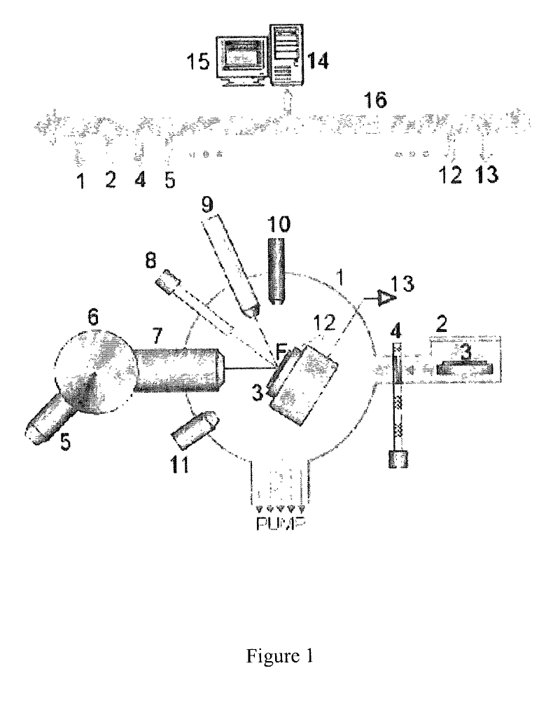

### TECHNOLOGY

This invention refers to the sphere of electronic and vacuum technology, in particular to the units for the formation of various structures and coatings on semiconductor wafers. It can be used to develop new-generation semiconductor devices, as well as in optical instrument-making.

### PREVIOUS TECHNOLOGICAL LEVEL

There exists a unit for processing of semiconductor wafers, which incorporates a vacuum unit, vacuum exhaust devices, and a wafer-processing device (Patent EP 0275965, M cl. HO1 J 37/32 1988). In this unit, with a single-wave transmission mode at a frequency of 2.45 GHz, the plasma beam cross-section and the diameter of the processed wafers are located in the range of 76-100 mm, while the plasma flow angle relative to the normal to the processed wafer surface is defined with an approximation.

This solution is regarded as the closest analog (prototype).

### CONTENTS OF INVENTION

The essence of this invention lies in the development of a unit for production of nanostructures suitable for making semiconductors with a high integration level, and high-resolution optical devices, and is aimed at enlarging the functionality of the existing unit.

The unit for the formation of nanostructures on semiconductor wafer surface incorporates a vacuum chamber equipped with exhaust and annealing systems, a semiconductor wafer input device, a source of ions with controlled power, a mass separator, an electron gun, a wafer holder, and an ion current meter. The unit is equipped with an ion beam transport column, a quadrupole mass analyzer, an optical microscope, and a computer. The axes of the ion beam transport column, the optical microscope and the electron gun are situated on the same plane with the normal to the semiconductor wafer in the working position, and intersect in one point located on the front surface of the wafer; the angle between their axes is the minimum one; the computer scans the ion beam through a set of sites by moving the wafer along the given site coordinates, and displays images of the wafer surface in secondary electrons, and provides for combining ion and electron beam solutions on the surface of the wafer.

The vacuum chamber achieves a vacuum of 5×10⁻¹⁰ torrs. The ion beam diameter can vary from 0.9 μm to 1.5 μm, with an ion energy value of 5 keV.

### SHORT DESCRIPTION OF DESIGN FIGURES

The invention is illustrated with graphic materials. The drawing representing the unit for nanostructure formation by ion beams on the semiconductor wafer surface contains ultrahigh-vacuum chamber 1 capable of creating vacuum of 5×10⁻¹⁰ torr, with the necessary exhaust and annealing systems (not shown on the drawing); semiconductor wafer input (into chamber 1) device 2 with a diameter of 200 mm; semiconductor wafer 3; gateway valve 4; source of ions with controlled power 5; mass separator 6; ion beam transport column 7; optical microscope 8; electron gun 9; quadrupole mass analyzer 10; electron detector 11; wafer holder 12; ion current meter 13, computer 14, monitor 15, interface 16.

### BEST IMPLEMENTATION OPTION

The technical result to be obtained from implementing the invention is production of thin-film semiconductor structures suitable for creating new-generation semiconductor devices and diffracting screens.

This result can be achieved as follows. Wafer 3 is placed in the vacuum chamber 1 with a residual pressure of 5-10⁻¹⁰ torr. A column source of the duoplasmatron type is filled with nitrogen to generate a nitrogen ion flow. The ion flow energy and wafer radiation angle values are set. An area of S=200×200 sq. μm on the wafer surface is evenly irradiated with a nitrogen ion flow under a current of I=250 nA. The following conditions are to be met. The axis of the ion beam transport column 7, the optical microscope 8, and the electron gun 9 must intersect in one point F located on the front side of the wafer 3 surface. This point must be the focal point of the ion beam transport column 7, the optical microscope 8, and the electron gun 9. The ion beam transport column 7, the optical microscope 8, and the electron gun 9 must be located on the front side of the wafer, and the angle between them must have the minimum value. The ion source 5 is a duoplasmatron-type source operating on such gases as argon, oxygen and nitrogen, and providing ion energy values in the range of 500 eV to 20 keV.

The mass separator 6 is a mass separator with a mass range from 1 to 100 a.e.m., and has a relative mass resolution of 5 a.e.m. The ion beam transport column 7 provides for changing the raster size and the raster side ratio. The ion beam diameter must be about 1 μm (from 0.9 μm to 1.5 μm) with an ion energy value of 5 keV. The X and Y directions of the ion beam scanning must coincide with the movement directions of the wafer holder 12. The electron control of the ion beam shift along the Y axis must not be less than the double raster size in the Y direction. The ion beam sweep linearity in the Y direction must be controlled.

The optical microscope 8 is made with wafer highlight, an 8-100-time magnification, and image display on the TV monitor. The electron gun 9 creates an electron energy value of 100 eV to 10 keV, an electron beam current of 5 μA, and spot size of about 100 nm. The X and Y ion beam scanning directions must coincide with the movement directions of the wafer holder 12.

The electron control of the ion beam shift along the Y axis must not be less than the double raster size in the Y direction.

The ion beam sweep linearity in the Y direction must be controlled.

The quadrupole mass analyzer 10 is equipped with the optics for gathering both positive and negative secondary ions.

The range of measured masses is from 1 to 100 a.e.m. The absolute mass resolution is 5 a.e.m. The electron detector 11 is a detector of secondary electrons.

The wafer holder 12 provides for wafer inclination in such a way that the normal to the wafer remains on the plane of the axes of the ion beam transport column 7, the optical microscope 8, and the electron gun 9. The inclination angle of the wafer normal to the ion beam transport column 7 axis must be from 0 to 90°. The wafer rotation must be from 0° to 360°. There is no need for continuous rotation. The angle precision must be ±0,5°. The wafer holder should provide for heating the wafer from the room temperature to 700° C. The X and Y wafer movement directions should lie on the wafer plane. The wafer movement in the Z direction should provide for superposing the wafer surface plane with the focal point of the ion beam transport column 7, the optical microscope 8, and the electron gun 9. The wafer movement error should be about 1 μm. The ion current meter 13 provides for measuring the current from the wafer.

The computer 14 with monitor 15 and interface 16 are designed for controlling the whole unit. The computer 14 scans the ion beam through a set of sites by moving the wafer along the given site coordinates, while the stopping of the ion beam should be defined by the wafer current integral, as well as by the signal of certain ions detected by the quadrupole mass analyzer 10.

The computer provides for receiving wafer surface images both in secondary electrons generated by the scanning electron or ion beams, and through the optical microscope 8, to superpose the ion and electron beam rasters on the wafer surface.

### INDUSTRIAL APPLICATION

This invention refers to the sphere of electronic and vacuum technology, in particular to the units for the formation of various structures and coatings on semiconductor wafers. It can be used to develop new-generation semiconductor devices, as well as in optical instrument-making. The invention can be used to create units for production of nanostructures suitable for making semiconductors with a high integration level, and high-resolution optical devices.

1. The unit for the formation of nanostructures on semiconductor wafer surface incorporating a vacuum chamber equipped with exhaust and annealing systems, a semiconductor wafer input device, a source of ions with controlled power, a mass separator, an electron gun, an electron detector, a wafer holder, and an ion current meter. The unit is equipped with an ion beam transport column, a quadrupole mass analyzer, an optical microscope, and a computer, the axes of the ion beam transport column, the optical microscope and the electron gun being situated on the same plane with the normal to the semiconductor wafer in the working position, and intersecting in one point located on the front surface of the wafer; the ion beam transport column, the optical microscope and the electron gun being situated on the front side of the wafer, and the angle between their axes is the minimum one; the computer scans the ion beam through a set of sites by moving the wafer along the given site coordinates, and displays images of the wafer surface in secondary electrons, and provides for combining ion and electron beam solutions on the surface of the wafer.

2. The unit of Paragraph 1, differing in that its vacuum chamber achieves a vacuum of 5×10⁻¹⁰ torr.

3. The unit of Paragraph 1, differing in that the ion beam diameter can vary from 0.9 μm to 1.5 μm, with an ion energy value of 5 keV.
